(19) United States
(12) Patent Application Publication
(10) Pub. No.: US 2011/0236592 A1
(43) Pub. Date: Sep. 29, 2011

(54) METHOD FOR TREATING A METAL ELEMENT WITH ION BEAM

(75) Inventor: Denis Busardo, Gonneville/mer (FR)

(73) Assignee: QUERTECH INGENIERIE, Caen (FR)

(21) Appl. No.: 13/132,190

(22) PCT Filed: Nov. 30, 2009
(86) PCT No.: PCT/FR09/52335

§ 371 Date: Jun. 1, 2011

(30) Foreign Application Priority Data
Dec. 1, 2008 (FR) 08 58182

(51) Int. Cl. C23C 14/48

(52) U.S. Cl. 427/528

(57) ABSTRACT

The present invention relates to a method for treating a metal element subjected to an ion beam, where: the ions of the beam are selected from among boron, carbon, nitrogen, and oxygen; the ion acceleration voltage, greater than or equal to 10 kV, and the power of the beam, between 1 W and 10 kW, as well as the ion load per surface unit are selected so as to enable the implantation of ions onto an implantation area with a thickness e_{I} of 0.05 μm to 5 μm, and also enable the diffusion of ions into an implantation/diffusion area with a thickness e_{I}+e_{P}, of 0.1 μm to 1,000 μm; the temperature T_{ZF} of the area of the metal element located under the implantation/diffusion area is less than or equal to a threshold temperature T_{SD}. In this manner, metal surfaces having remarkable mechanical characteristics are advantageously produced.

The invention relates to a method for treating a metal element of a part in which a surface of said metal element is subjected to an ion beam in a manner that implants ions of the beam in an implantation area.

In particular, the invention relates to treating the surface of said element of the part in a manner that enhances its mechanical properties.

Several techniques are known for improving the mechanical properties of the surface of a metal element.

For example, in nitriding, a thermochemical treatment enriches superficial areas of a metal element with nitrogen.

Nitriding may be done using a plasma, particularly a cold plasma, generated at low pressures by radio frequency excitation. The part to be treated is maintained at a high temperature in a furnace to allow the diffusion of the nitrogen ions. This technique has the disadvantage of requiring a temperature where the metal of the metal element of the part to be treated may undergo undesirable transformations which may cause a loss of the mechanical qualities of the treated metal element, particularly in the case of aluminum alloys.

Nitriding can also be achieved by ion implantation, in which nitrogen ions are accelerated by voltages of a few kV to several hundred kV and bombard the surface of the metal element being treated. The part to be treated is generally cold. In this manner significant quantities of nitrogen can be implanted. However, the depth of penetration of the nitrogen ions is generally limited to 1-1.5 μm.

Other nitriding techniques are known such as thermal nitriding, which allows the nitrogen to penetrate to fairly significant thicknesses.

A part is maintained at a high temperature in a nitrided atmosphere for long periods. Structural transformations may result in the metal of the part being treated.

It has also been observed that in nitriding methods where the part to be treated is brought to a high temperature, there are disadvantages in terms of the risk of deformation after treatment when the part cools down from these high temperatures.

The object of the invention is to overcome these disadvantages.

The invention proposes a method for treating a metal element, of a thickness e_{M}, of a part, wherein a surface of said metal element is subjected to an ion beam so as to implant ions of the beam into an implantation area (ZI) of a thickness e_{I}, wherein:
the ions of the beam are selected from among the ions of the elements in the list consisting of boron (B), carbon (C), nitrogen (N), and oxygen (O);
the ion acceleration voltage is greater than or equal to kV, the beam power is between 1 W and 10 kW, and said acceleration voltages and beam power as well as the dose of ions per unit of surface area are chosen to allow the implantation of ions from the beam into an implantation area (ZI) having a thickness e_{I} of between 0.05 μm and 5 μm, and to allow the diffusion of ions into an implantation-diffusion area (ZID) of a thickness e_{I}+e_{D} that is greater than e_{I} and between 0.1 μm and 1000 μm;
the temperature T_{ZF} of the area (ZF) of the metal element being treated, situated under the implantation-diffusion area (ZID), is less than or equal to a threshold temperature T_{SD} where T_{SD} is a temperature at which the ions of the beam travel 50 nm in 100 seconds in the metal of said metal element.

It is thus possible to enhance the mechanical properties of the surface of a metal element by introducing the selected atoms to a significant depth in the metal element being treated while avoiding any heating of the part to high temperatures. This avoids the risk of metallurgical transformation of the part during the treatment, and, because of the low or moderate temperature during the treatment of the part, it also avoids the risk of deformation after the part cools.

Without being tied to a particular scientific theory, it can be suggested that the ion beam used under the conditions of the invention acts as a heated tip and first implants ions on the surface, then enables their diffusion to greater thicknesses. One can hypothesize that the conditions in the invention allow “recovering” the heat released by the slowing of the beam ions in the metal element of the part being treated and thus allow these ions to diffuse beyond the implantation area without requiring the contribution of additional heat. The resulting method is particularly advantageous in terms of energy cost. The heat energy is thus contributed in a very localized manner by the beam ions and it is no longer necessary to heat the part to enable the ions to diffuse to significant depths. It is therefore possible in the invention to nitride titanium, steels, alloys of aluminum or other metals and alloys to thicknesses of several micrometers and to obtain remarkable hardness values at significant thicknesses.

In the invention, the choice of conditions for adjusting the ion beam within certain ranges of values advantageously allows choosing the thicknesses of the implantation area and the implantation-diffusion area based on the desired results. It is therefore possible to choose these conditions according to the desired hardness, the type of part to be treated, the type of metal of the metal element to be treated, and the industrial conditions under which this treatment method is applied. For example, it is possible to choose the values for the acceleration voltage and the beam power as a function of the desired treatment speeds.

The present treatment method can be implemented with multiple ions, independently or concurrently, chosen from among boron, carbon, nitrogen, and oxygen. In one embodiment, the ions of the beam are nitrogen ions.

The inventors were able to demonstrate that an acceleration voltage greater than or equal to 10 kV and a beam power greater than or equal to 1 W are necessary for an implantation of ions capable of diffusing at least partially over a thickness greater than the thickness of the implantation area. The acceleration voltage is defined as the voltage which enables giving the ions their kinetic energy. The beam power is equal to the intensity of the ions produced, multiplied by the acceleration voltage.

The implantation area may have a low thickness e_{I} of between 0.05 and 0.2 μm, a moderate thickness e_{I} of between 0.2 and 1 μm, corresponding to the most common implantation conditions, or even a high thickness e_{I} of between 1 and 5 μm if the ion beam is very high in energy.

Under the conditions of the invention, a portion of the implanted ions diffuses beyond the implantation area of thickness e_{I}, to a depth e_{I}+e_{D}, where e_{D} corresponds to the thickness of the area where the ions can diffuse beyond the implantation area of thickness e_{I}.

The thickness e_{D} of the diffusion area may be low and between 0.1 and 0.5 μm, may be moderate and between 0.5 and 10 μm, and may be high and between 10 and 100 μm or even very high and reach up to 1000 μm if the ion beam is very high in energy.

In one embodiment, the thickness e_{D} of the diffusion area is greater than or equal to the thickness e_{I} of the implantation area.

By choosing a temperature of the area of the metal element of the part being treated that is less than the threshold temperature T_{SD}, it is possible to ensure that the ions of the beam cannot diffuse beyond the desired thickness. This provides precise control of the treatment thickness. It is also possible to ensure that the core of the metal element being treated is not brought to a temperature at which undesired metallurgical changes are likely to occur. Similarly, as only the implantation and diffusion areas are heated in a controlled manner by the energy contributed by the ion beam, any disadvantageous deformations in the part when it cools are avoided.

In order to maintain at a temperature less than T_{SD} the area situated under the implantation-diffusion area of the metal element being treated, it is possible to cool the part by any means known to a person skilled in the art.

The inventors were able to determine that a threshold temperature T_{SD}, at which the ions of the beam travel 50 nm in 100 seconds in the metal of the element being treated, avoids significant diffusion of these ions beyond the implantation and diffusion areas.

The invention can have numerous applications in a wide variety of industrial fields in which it is advantageous to improve the surface properties of metal elements, such as the automobile industry, the space industry, or in the field of electrical connectors.

In one embodiment of the invention, the metal of the metal element is chosen from among the following list of metals: magnesium (Mg), aluminum (Al), titanium (Ti), vanadium (V), chromium (Cr), iron (Fe), cobalt (Co), nickel (Ni), copper (Cu), zinc (Zn), zirconium (Zr), silver (Ag), hafnium (Hf), tantalum (Ta), iridium (Ir), platinum (Pt), gold (Au), molybdenum (Mo), tungsten (W), niobium (Nb), or the alloys of each of these metals.

To enable the diffusion of an implanted ion, the implantation area is exposed to a diffusion temperature for a sufficient period of time. The diffusion distance of the ion can be calculated using the following formula: (2*D*t)^{1/2}, where D represents the diffusion coefficient for the ion in the metal at a given temperature and t is the exposure time at this temperature. The diffusion coefficient for the ion in the metal increases with the temperature. Beyond the threshold diffusion temperature, the diffusion distances of the ion become significant relative to the implantation depths. For example, the threshold diffusion temperature for nitrogen in aluminum alloys is estimated to be 400° C.

In one embodiment of the invention, the temperature T_{SD} is a temperature at which the ions of the beam have a diffusion coefficient equal to 10⁻¹⁷ m²·s⁻¹ in the metal of said metal element.

In one embodiment of the invention, the temperature T_{S} of the area of the surface of the metal element bombarded by the ion beam is greater than or equal to a threshold temperature T_{SID}, where T_{SID} (in Kelvin)=1.1×T_{SD} (in Kelvin).

The temperature T_{S} is understood to mean the measured temperature at the surface of the metal element of the part being treated in the portion of this surface during treatment, meaning during the bombardment of this portion of the surface by the ion beam.

Choosing a temperature T_{S} that is greater than or equal to a threshold temperature T_{SID} as defined results in conditions where the diffusion in the implantation and diffusion areas is particularly effective.

The inventors were able to determine that a threshold value T_{SID}=1.1×T_{SD}, where the temperatures are expressed in Kelvin, obtains these advantageous conditions. It is then possible to deduce advantageous conditions for the acceleration voltage and beam power.

In one embodiment, the area of the metal element being treated is of limited dimensions and the part does not move relative to the ion beam.

In another embodiment, the part moves relative to the ion beam.

The part may move while the ion beam remains fixed, or conversely the part may be fixed and the beam may have a means for displacing its section that is interacting with the part. It is also possible to combine a displacement of the part and of the ion beam. When the ion beam moves relative to the surface of the metal element of the part being treated, a heated point can be considered to be created at each location where the ion beam passes. At a given location on this surface, the heated point results in an increase in temperature when the beam reaches this location, then a maximum temperature at this location followed by a drop in the temperature to the initial temperature of said metal element.

In one embodiment, the cross-section of the ion beam interacting with the metal element of the part being treated moves at a constant speed relative to this metal element, called the scan rate V.

In such an embodiment, in which the beam has a circular cross-section, one can determine the power P, scan rate V, and radius R of the ion beam for a given temperature T_{S} such that the following equation is satisfied:

T_{S}=(4*P*(2*R/V)^{1/2})/(ρ*C*π*R²*(4*π*(γ/ρ*C))^{1/2})+T_{ZF}

where:

T_{S} is expressed in Kelvin;
T_{ZF} is the temperature of the metal element of the part under the implantation-diffusion area and is less than or equal to T_{SD}, expressed in Kelvin;
P is the power of the ion beam (in W);
R is the radius of the ion beam (in m);
V is the scan rate of the ion beam (in m·s⁻¹);
ρ is the density of the metal of the metal element (in kg·m⁻³);
C is the heat capacity of the metal of the metal element (in J·kg⁻¹·K⁻¹);
γ is the thermal conductivity of the metal of the metal element (in W·m⁻¹·K⁻¹).

It is understood that this invention is not limited to the case where the ion beam has a circular cross-section, and that any other beam shape can be used.

In some embodiments, which may be combined:
the ion beam has a scan rate V of between 0.01 mm/s and 1000 mm/s, for example greater than or equal to 1 mm/s and/or less than or equal to 100 mm/s, and a radius of between 0.1 mm and 100 mm, for example greater than or equal to 1 mm and/or less than or equal to 50 mm;
the power of the ion beam is greater than or equal to 10 W and/or less than or equal to 2000 W, for example less than or equal to 1000 W;
the dose of ions per unit of surface area is greater than or equal to 10¹⁸ ions/cm², for example greater than or equal to 2×10¹⁸ ions/cm², or even for example greater than or equal to 4×10¹⁸ ions/cm²;
the ion beam makes a pass or a plurality of passes over the same area of the surface of the metal element being treated, and the dose of ions per unit of surface area and per pass is greater than or equal to 0.5×10¹⁷ ions/cm² per pass, for example greater than or equal to 1×10¹⁷ ions/cm² per pass, or even for example greater than or equal to 2×10¹⁷ ions/cm² per pass; in one embodiment, the dose of ions per unit of surface area and per pass is additionally less than or equal to 100×10¹⁷ ions/cm² per pass, for example less than or equal to 50×10¹⁷ ions/cm² per pass or even less than or equal to 20×10¹⁷ ions/cm² per pass;
the thickness e_{I} of the implantation area (ZI) is greater than or equal to 0.1 μm and/or less than or equal to 1 μm;

the thickness e_{I}+e_{D} of the implantation-diffusion area (ZID) is greater than or equal to 1 μm and/or less than or equal to 100 μm, for example less than or equal to 10 μm.

In one embodiment of the invention, the diameter of the beam and the displacement speed of the beam relative to the part can be adjusted to produce, for a desired exposure period, a heated point which exceeds a threshold diffusion temperature without ever exceeding the melting point of the metal. Thus at a given location in the metal element, the implanted ion is allowed to diffuse to the desired depth. If the length of exposure is insufficient, the operation can be repeated multiple times by making several passes. Between two successive passes the superficial temperature of the part falls to its initial value.

One will note that the angle of incidence of the beam can vary as a function of the geometry of the metal element being treated. When at a given point the beam has an angle of incidence which is not 0°, the decrease in its power per unit of surface area can be compensated for by proportionally reducing the speed of the beam.

In one embodiment of the invention, the ion source is an electron cyclotron resonance (ECR) source, which is compact, light, consumes little power, and produces a stable and reproducible beam for the duration. The stability of the ion beam so generated is advantageous for producing the heated point. Filament sources are generally less reliable. In addition, ECR sources produce multicharged ions which are much higher in energy at equivalent acceleration voltages. The ions produced penetrate to significant depths with little sputtering at the surface. Large treatment thicknesses can be obtained in this manner.

One will note that it is possible to modify certain characteristics of the beam when needed. For example, when the initial ion beam is not powerful enough to create the desired heated point, a magnetic lens can reduce the diameter of the ion beam to concentrate more power per unit of surface area. The minimum diameter can be determined by the increment by which a relative displacement system advances. The position and speed of the part/beam relative displacement system can be controlled to create a heated point of sufficient heat to diffuse the implanted ion without exceeding the melting point of the metal.

The increment by which the beam advances can be calculated to provide coverage of the superficial diffusion areas of the ion. For example, if it is estimated that the ion diffuses in a circle centered around the axis of the beam having a radius corresponding to half that of the beam, the beam can be advanced by an increment that is the radius of this diffusion circle, meaning half the radius of the beam.

As an example, one can multiply the number of passes so as not to exceed a maximum desired atomic concentration in the thickness implanted and diffused. As an example, it can be considered advantageous not to exceed an atomic concentration of 50% in the case of nitrogen.

To apply the invention, it is advantageous to control the different parameters using a computerized system. The displacement system can be managed with post-processing produced on a CAD/CAM system, based on a digital model of the metal element to be treated. Using the digital model, it is possible to know the angle of incidence of the beam at each point of its passage over the surface of the metal element. This information can be utilized to weight the speed of the beam in order to produce an optimum heated point on the surface of the part.

In one embodiment of the invention, the metal of the metal element is titanium (Ti) or a titanium alloy and:

T_{ZF}≦773 K and

T_{S}≧973 K.

The following exemplary treatment conditions can advantageously be implemented using a titanium alloy:

P=300 W, V=1 mm·s⁻¹, R≦10 mm;

P=30 W, V=1 mm·s⁻¹, R≦2.5 mm;

P=300 W, V=10 mm·s⁻¹, R≦5 mm;

P=30 W, V=10 mm·s⁻¹, R≦1 mm.

In another embodiment, the metal of the metal element is iron (Fe) or an iron alloy, particularly a stainless steel, and:

T_{ZF}≦393 K and

T_{S}≧473 K.

The following exemplary treatment conditions can advantageously be implemented using alloy steel:

P=300 W, V=1 mm·s⁻¹, R≦22 mm;

P=30 W, V=1 mm·s⁻¹, R≦5.5 mm;

P=300 W, V=10 mm·s⁻¹, R≦10 mm;

P=30 W, V=10 mm·s⁻¹, R≦2.25 mm.

In another embodiment, the metal of the metal element is aluminum (Al) or an aluminum alloy, and:

T_{ZF}≦543 K and

T_{S}≧597 K.

The following exemplary treatment conditions can advantageously be implemented using an aluminum alloy:

P=300 W, V=1 mm·s⁻¹, R≦10 mm;

P=30 W, V=1 mm·s⁻¹, R≦2.5 mm;

P=300 W, V=10 mm·s⁻¹, R≦4.8 mm;

P=30 W, V=10 mm·s⁻¹, R≦1 mm.

Other features and advantages of the invention will be apparent from the following description of some non-limiting examples, with reference to the attached drawings in which:

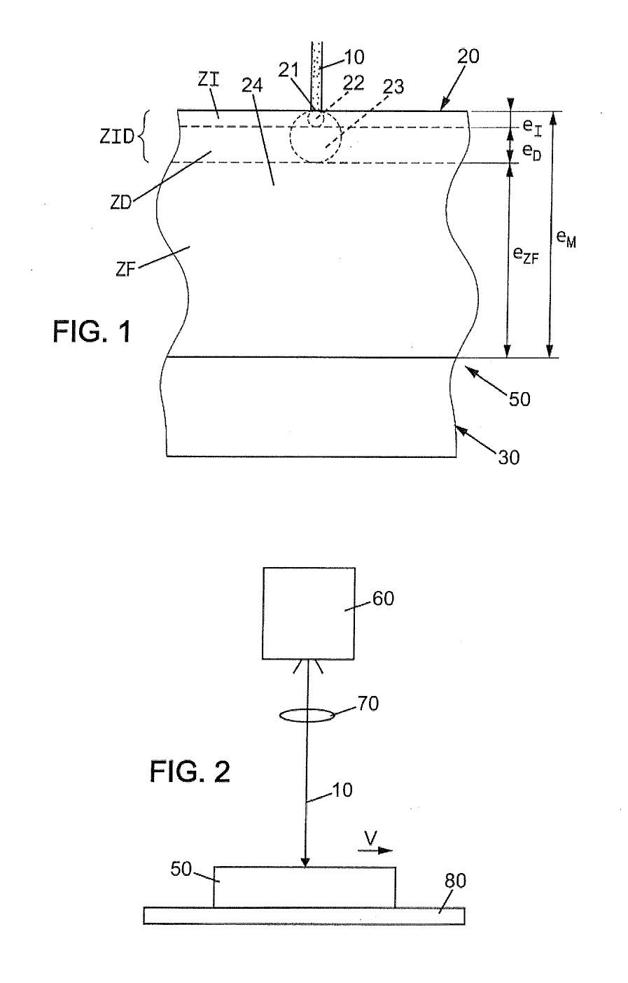

FIG. 1 is a schematic cross-sectional view of a part to be treated according to the invention;

FIG. 2 is a schematic view of a device for implementing the method of the invention;

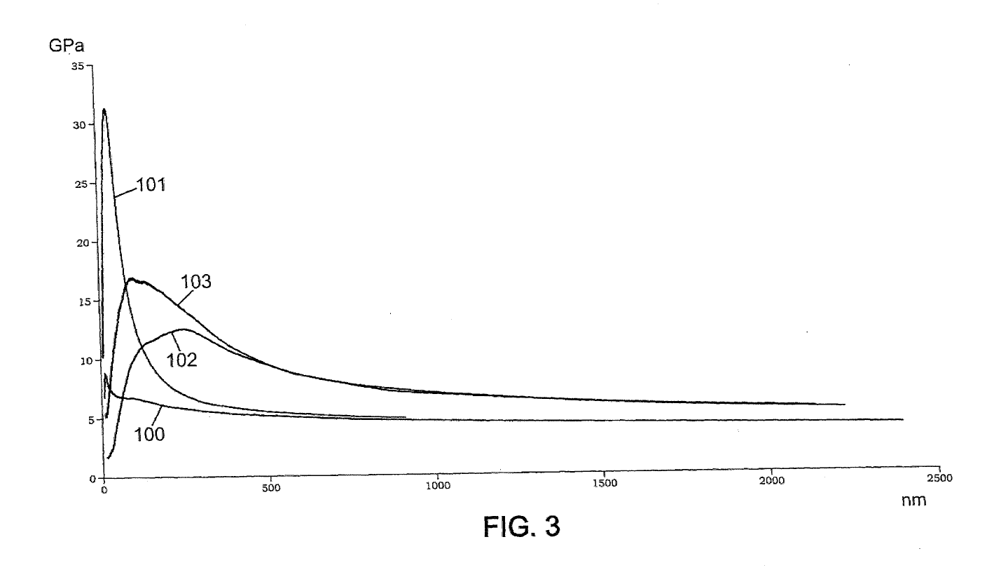

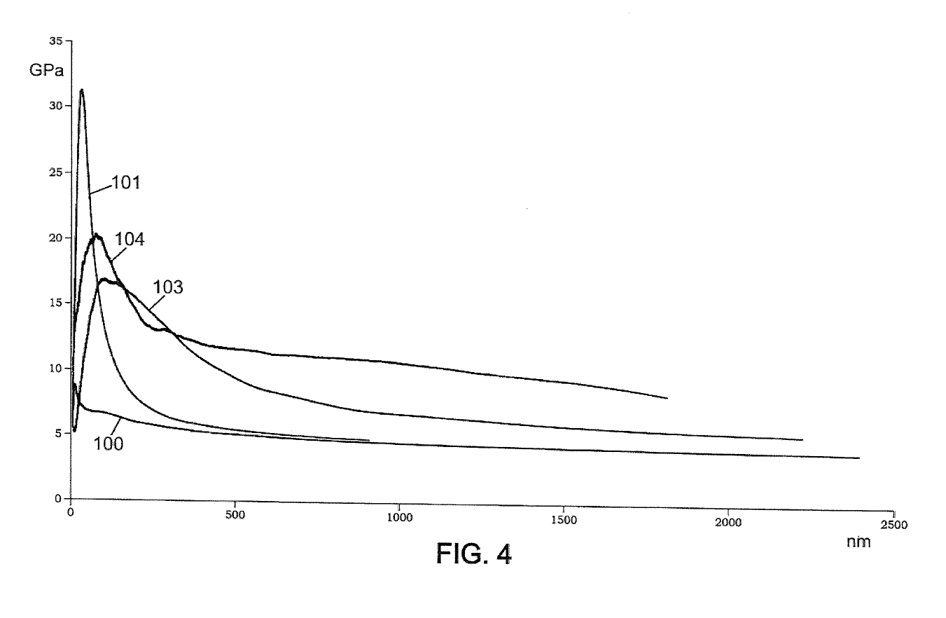

FIGS. 3 and 4 are graphs showing the variation in hardness as a function of the thickness of titanium samples, treated according to the invention but under different conditions;

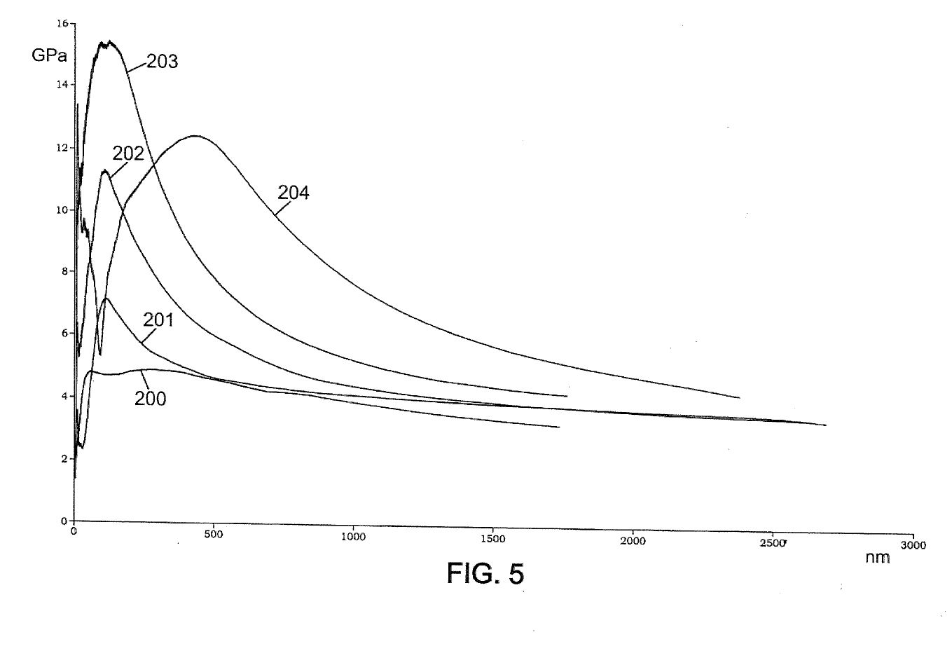

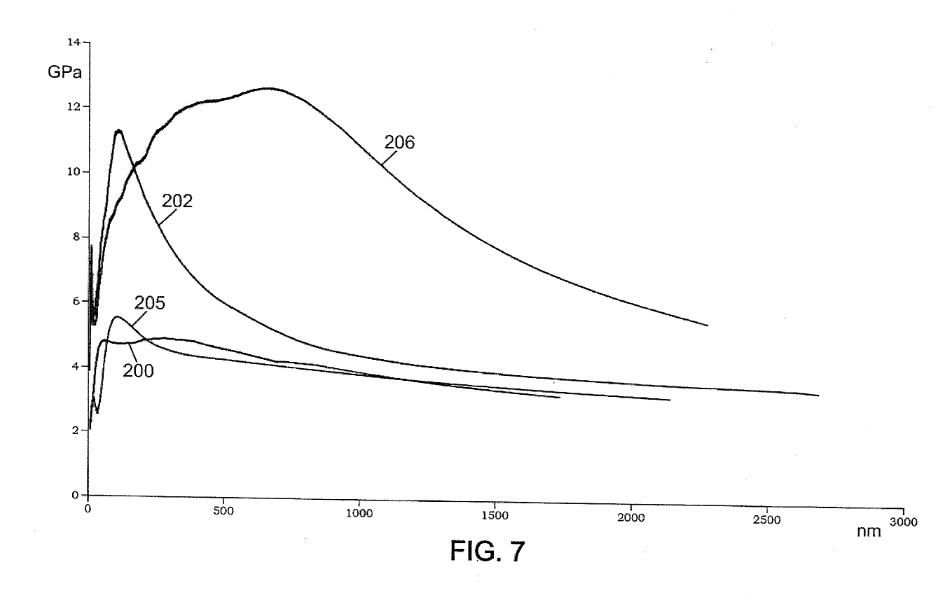

FIGS. 5 and 7 are graphs showing the variation in hardness as a function of the thickness of steel samples, treated according to the invention but under different conditions;

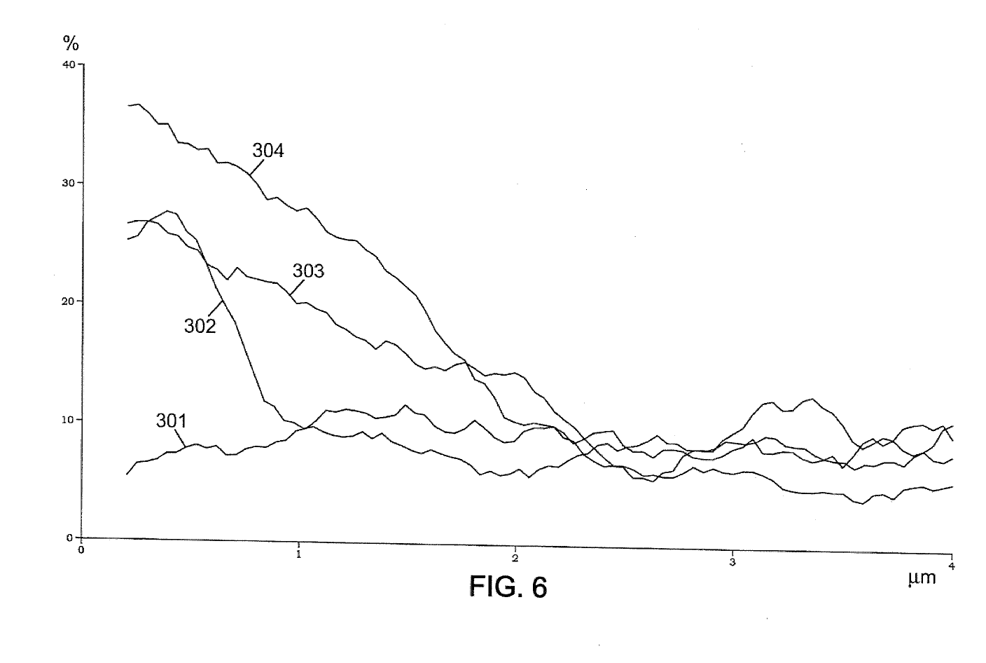

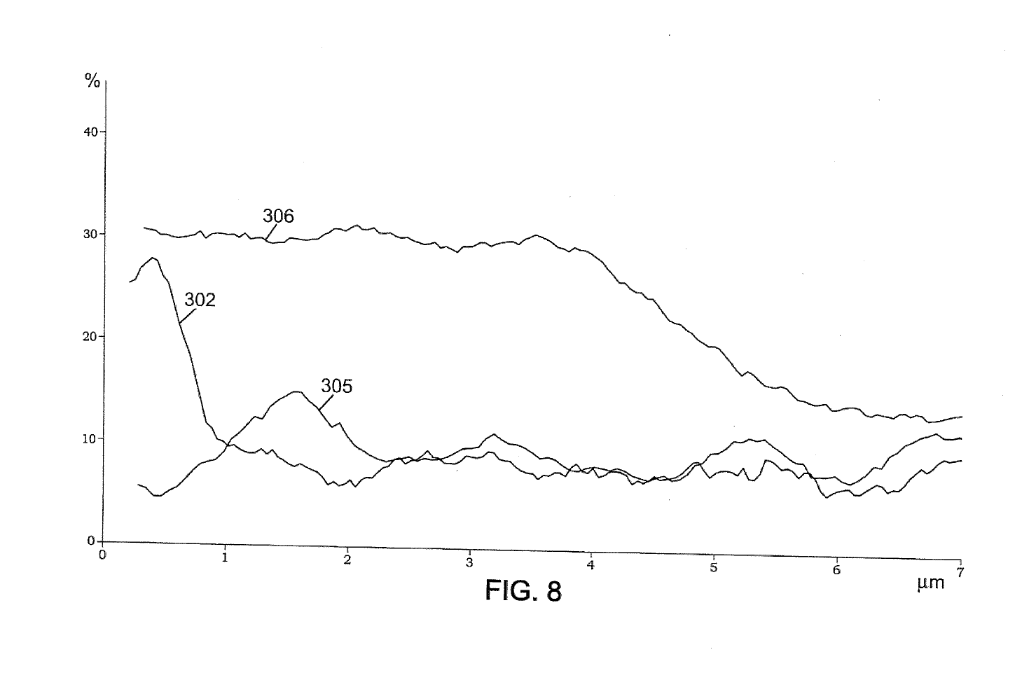

FIGS. 6 and 8 are graphs showing the concentration of nitrogen as a function of the thickness corresponding to the treatment conditions in FIGS. 5 and 7;

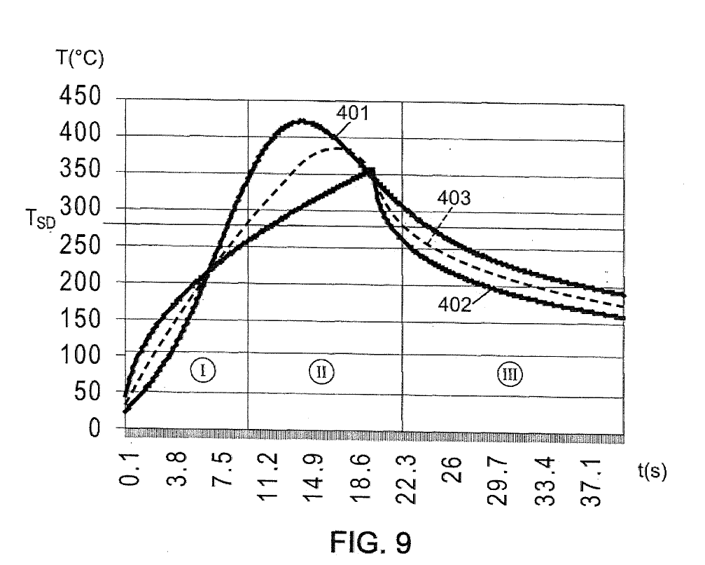

FIG. 9 shows some temperature profiles related to the implantation-diffusion of nitrogen in an aluminum alloy during treatments according to the invention.

For clarity, the dimensions of the different elements represented in these figures are not necessarily in proportion to their actual dimensions.

FIG. 1 represents a portion of a part 50 which comprises a metal element 20 of thickness e_{M}. In the example represented, this metal element 20 is on top of another element 30 of the part 50. It is understood that the part 50 may be composed solely of the metal of the metal element 20.

The metal element 20 is subjected to treatment by an ion beam 10. The ion beam is adjusted according to the invention to allow the creation of an implantation area ZI of thickness e_{I}, and a diffusion area ZD of thickness e_{D}. “Implantation-diffusion area” as used below refers to the area ZID consisting of the implantation area ZI and diffusion area ZD.

The area ZF of the metal element, situated under the implantation-diffusion area and of thickness e_{ZF}, is maintained in the invention at a temperature T_{ZF} that is less than or equal to a threshold temperature T_{SD}.

The ions of the beam 10 are directed onto an area of the surface 21 of the metal element 20 being treated. These ions are implanted in the area ZI under the area of impact of the ion beam, in a region 22. Because the heat contributed by these ions interacts with the metal, a diffusion of a portion of these ions occurs which allows their displacement into a region 23 around the region 22. The region 24 of the area ZF is maintained at a temperature that does not allow significant diffusion of the ions into it.

FIG. 2 is a schematic view of a device for implementing the method of the invention, in which an ECR source 60 delivers an ion beam 10 of a given power and diameter. The part 50 is arranged on a displacement means 80 which allows the part to move at a speed V relative to the beam 10. It is possible to have a cooling means between the displacement means and the part 50 to be treated, in order to maintain the desired temperature T_{ZF} in the area ZF.

A magnetic lens 70 can be implemented in order to adjust the diameter of the ion beam 10 as a function of the desired power per unit of surface area on the metal element of the part being treated.

The displacement means 80 can be activated to allow several passes of the ion beam over the same area of the surface being treated.

FIGS. 3, 4, 5 and 7 represent curves graphing the hardness, expressed in GPa, as a function of the depth, expressed in nanometers, in the metal element 20 of the part being treated, starting from the treatment surface 21.

These measurements are made by nanoindentation, using a nano hardness tester with a diamond point. The advancement of the point under the effect of a load is measured on the nanometric scale.

The graphs 3 and 4 show the hardness measurement results for samples in which the treated alloy is a titanium alloy Ti-6% Al-4% V, known commercially as TA6V.

Curve 100 corresponds to the hardness profile for a part made of untreated TA6V. Its hardness is less than 9 GPa across the entire thickness and is substantially between 6 and 8 GPa.

Curve 101 corresponds to the hardness profile for a part made of TA6V treated by a nitrogen implantation method under known implantation conditions; under these conditions the acceleration voltage of the ions is 46,000 V, the power of the beam is 315 kW, the beam scan rate V is fast (40 mm/s) with a large number of passes (72 passes) in the same area of the surface of the metal element being treated, and the dose of ions per unit of surface area is equal to 5.4×10¹⁷ ions/cm². The resulting dose of ions per unit of surface area and per pass is equal to 0.07×10¹⁷ ions/cm² per pass. The hardness of the sample obtained in this way has a maximum of about 30 GPa at a depth of about 50 nm. One will note that the improvement in the hardness rapidly diminishes as a function of the thickness and that the hardness profile of this sample returns to near that of an untreated sample at about 200 nm.

The other curves 102 to 104 represented in FIGS. 3 and 4 result from measurements for samples of TA6V treated with nitrogen ions according to the invention, under the following conditions:

Acceleration voltage: 46 000 V

Beam power: 315 kW

Temperature T_{ZF}: 300 K

The following parameters were varied:

In FIG. 3, the number of passes over the same area of the surface of the metal element being treated was varied under the following conditions:

| | | | Surface dose |
|---|---|---|---|
| | Number of | Speed | (in 10¹⁷ |
| Curve | passes | (in mm/s) | ions/cm²) |
| 102 | 4 | 0.2 | 60 |
| 103 | 6 | 0.2 | 89 |

Resulting from these treatment conditions are ion doses per unit of surface area and per pass of between 15×10¹⁷ ions/cm² per pass.

In FIG. 4, the scan rate V is varied under the following conditions:

| | | | Surface dose |
|---|---|---|---|
| | Number of | Speed | (in 10¹⁷ |
| Curve | passes | (in mm/s) | ions/cm²) |
| 103 | 4 | 0.2 | 60 |
| 104 | 8 | 0.4 | 60 |

Resulting from these treatment conditions are ion doses per unit of surface area and per pass of between 7×10¹⁷ and 15×10¹⁷ ions/cm² per pass.

Under these conditions, it is observed that implantation-diffusion phenomena occur and that the nitrogen ions allow obtaining a temperature T_{S} in the area of the surface of the metal element bombarded by the ion beam that is greater than a threshold temperature T_{SID}, estimated to be 973 K for a titanium alloy.

In fact, for the set of curves 102 to 104 concerning samples of TA6V treated according to the invention, a very significant increase in the hardness is observed in an area near the surface of between about 80 and 300 nm; there is a noteworthy increase in hardness compared to an untreated sample at very significant depths of greater than 1000 nm, or even greater than several μm. The increase in the hardness at such thicknesses results from the diffusion of nitrogen ions implanted on the surface towards the core of the metal element. It is thus possible to harden a titanium alloy to a great depth and to give it remarkable surface properties.

Graphs 5 and 7 report results from hardness measurements performed on samples in which the treated alloy is a steel commercially referred to as 304L.

Curve 200 corresponds to the hardness profile for a part of untreated 304L steel. Its hardness is about 5 GPa.

The other curves 201 to 206, represented in FIGS. 5 and 7, result from measurements for 304L samples treated with nitrogen ions according to the invention under the following conditions:

Acceleration voltage: 46 000 V

Beam power: 315 kW

Temperature T_{ZF}: 300 K

The following parameters were varied:

In FIG. 5, the number of passes within the same area of the surface of the metal element being treated within the same area were varied under the following conditions:

| | | | Surface dose |
|---|---|---|---|
| | Number of | Speed | (in 10¹⁷ |
| Curve | passes | (in mm/s) | ions/cm²) |
| 201 | 13 | 1 | 40 |
| 202 | 26 | 1 | 80 |
| 203 | 39 | 1 | 120 |
| 204 | 52 | 1 | 160 |

Resulting from these treatment conditions are ion doses per unit of surface area and per pass of 3×10¹⁷ ions/cm² per pass.

In FIG. 7, the scan rate V is varied under the following conditions:

| | | | Surface dose |
|---|---|---|---|
| | Number of | Speed | (in 10¹⁷ |
| Curve | passes | (in mm/s) | ions/cm²) |
| 202 | 26 | 1 | 80 |
| 205 | 52 | 2 | 80 |
| 206 | 13 | 0.5 | 80 |

Resulting from these treatment conditions are ion doses per unit of surface area and per pass of between 1.5×10¹⁷ and 6×10¹⁷ ions/cm² per pass.

Under these conditions, it is observed that implantation-diffusion phenomena occur and that the nitrogen ions allow obtaining a temperature T_{S} in the area of the surface of the metal element bombarded by the ion beam that is greater than a threshold temperature T_{SID}, estimated to be 473 K for a steel.

In fact, for all the curves 202 to 206 concerning samples of steel treated according to the invention, a very significant increase is observed in the hardness in a first area of between about 100 and 800 nm, starting from the surface; a noteworthy increase in hardness is observed compared to an untreated sample at very significant depths of greater than 1000 nm, or even greater than several μm. The increase in hardness at such thicknesses results from the diffusion of the nitrogen ions implanted on the surface towards the core of the metal element. It is thus possible to harden a steel to a great depth and to give it remarkable surface properties.

These observations are corroborated by the nitrogen concentration profiles (expressed in atom % as a function of the depth expressed in μm) shown in FIGS. 6 and 8, in which the nitrogen concentration profiles are measured by EDS in sample slices. Profiles 301 to 306 respectively correspond to the samples for which the hardnesses were reported in FIGS. 5 and 7 and numbered 201 to 206. One will note that for all these curves, at least 5% nitrogen was introduced to a depth exceeding 5 μm, allowing an increase in the hardness at very significant depths. It should be noted that a nitrogen implantation method applied under known conditions results in a concentration profile where the nitrogen does not penetrate to more than about 0.2 μm.

FIG. 9 illustrates temperature profiles concerning the implantation-diffusion of nitrogen in an aluminum alloy in treatments according to the invention. The represented results were obtained by calculation and allow simulating the heated point caused by the passage of a 400 W beam of a radius of 15 mm, traveling at a speed of 1 mm/s over a metal element made of an aluminum alloy. The threshold temperature T_{SD} is estimated to be 543 K and the melting point is 660° C. Here the heated point is calculated from the Fourier equation in its one-dimensional form. This equation takes into account the diffusivity of the heat, which is specific to the metal. For an aluminum alloy the thermal diffusivity is estimated to be 5.4×10⁻⁵ m·s². The x axis shows the time expressed in seconds, corresponding to the passage of the beam at a given point. On the y axis the temperature of this point is expressed in degrees Celsius.

For a beam having a Gaussian profile, the temperature profile 401 would be observed; for a beam of constant profile, the temperature profile 402 would be observed. It is believed that the profile of a common beam is between the two above configurations and therefore has the estimated temperature profile 403.

Note that in a first area I, for a time of up to about 10 seconds, the temperature is less than T_{SD}. In a second area II, for a time of about 10 seconds to about 22 seconds, the temperature is greater than T_{SD}. In a third area III, for a time of beyond about 22 seconds, the temperature is less than T_{SD}. The nitrogen atoms cannot significantly diffuse in the areas I and III, while they can in the area II.

One will also note that the temperature remains less than the melting point of an aluminum alloy, which is estimated to be about 660° C.

The distances traveled by nitrogen in an aluminum alloy have been calculated for temperatures of 400° C. and 500° C. and different exposure times. At 400° C., the diffusion of nitrogen exceeds a half-micron for a duration of 100 seconds. At 500° C., values on the order of a micron are reached in several dozen seconds. The diffusion distance is added to the implantation thickness.

For example, with an acceleration voltage of 60 kV, three charge states N+(2.4 mAe), N2+(3 mAe), N3+(1 mAe), for an exposure of 15 seconds, a thickness of about 0.7 microns is nitrided by ion implantation with an average atomic concentration of nitrogen of 9.37%. If the beam displacement conditions are such that a heated point of between 400 and 500° C. is created for 15 seconds, the nitrogen must diffuse over a distance of between 0.25 and 0.85 microns. The total treated thickness, including the diffusion distance, therefore varies between about 0.95 and 1.55 microns. The mean atomic concentration of the nitrogen diffused in this thickness varies between about 6.9% and 4.2%. If the operation is repeated 5 times, a nitrided thickness of at least 2.3 micron and at most 5.8 micron is created in 90 seconds. By multiplying the operations, the depth of the nitrided thickness is increased, as well as the mean concentration of nitrogen in this thickness. One can additionally believe that the mean concentration of nitrogen may approach a limit concentration at the surface which depends on the nitrogen diffusion produced at each operation, from the sputtering due to the implantation.

The invention is not limited to the embodiments described in these examples and is to be interpreted in a non-limiting manner which includes any equivalent embodiment. It should be noted that although examples of treating titanium, steel, and aluminum were presented, the method of the invention can be implemented with many different metals in order to improve their surface properties.

1-15. (canceled)

16. A method for treating a metal element of a part, wherein the metal element has a thickness e_{M}, the method comprising:
subjecting a surface of said metal element to an ion beam so as to implant ions of the beam into an implantation area of the metal element, the implantation area having a thickness
wherein the ions of the beam are selected from among the ions of the elements in the list consisting of boron (B), carbon (C), nitrogen (N), and oxygen (O),
wherein an acceleration voltage for accelerating the ion beam is greater than or equal to 10 kV, the beam has a beam power of between 1 W and 10 kW, and said acceleration voltage and beam power as well as a dose of ions per unit of surface area are chosen to allow the implantation of ions from the beam into the implantation area with a thickness e_{I} of between 0.05 μM and 5 μm, and to allow diffusion of ions into an implantation-diffusion area having a thickness e_{I}+e_{D} greater than e_{I} and between 0.1 μm and 1000 μm;
the temperature T_{ZF} of an area of the metal element being treated, situated under the implantation-diffusion area, is less than or equal to a threshold temperature T_{SD} where T_{SD} is a temperature at which the ions of the beam travel 50 nm in 100 seconds in the metal of said metal element.

17. A treatment method according to claim 16, wherein the metal of the metal element is chosen from among the following list of metals: magnesium (Mg), aluminum (Al), titanium (Ti), vanadium (V), chromium (Cr), iron (Fe), cobalt (Co), nickel (Ni), copper (Cu), zinc (Zn), zirconium (Zr), silver (Ag), hafnium (Hf), tantalum (Ta), iridium (Ir), platinum (Pt), gold (Au), molybdenum (Mo), tungsten (W), niobium (Nb), or alloys of each of these metals.

18. A treatment method according to claim 16, wherein T_{SD} is the temperature at which the ions of the beam have a diffusion coefficient equal to 10⁻¹⁷ m²·s⁻¹ in the metal of said metal element.

19. A treatment method according to claim 16, wherein the temperature T_{S} of the area of the surface of the metal element bombarded by the ion beam is greater than or equal to a threshold temperature T_{SID}, where T_{SID} (in Kelvin)=1.1×T_{SD} (in Kelvin).

20. A treatment method according to claim 19, wherein the ion beam moves relative to the surface of the metal element at a scan rate V, and has a radius R and a power P; a temperature T_{S} of the area of said surface bombarded by the ion beam is chosen to be greater than or equal to a threshold temperature T_{SID}, and P, V, R are determined so as to satisfy the equation:
T_{S}=(4*P*(2*R/V)^{1/2})/(ρ*C*π*R²*(4*π*(γ/ρ*C))^{1/2})+T_{ZF}
where:
T_{S} is expressed in Kelvin;
T_{ZF} is the temperature of the metal element of the part under the implantation-diffusion area and is less than or equal to T_{SD}, expressed in Kelvin;
P is the power of the ion beam (in W);
R is the radius of the ion beam (in m);
V is the scan rate of the ion beam (in m·s⁻¹);
ρ is the density of the metal of the metal element (in kg·m⁻³);
C is the heat capacity of the metal of the metal element (in J·kg⁻¹·K⁻¹);
γ is the thermal conductivity of the metal of the metal element (in W·m⁻¹·K⁻¹).

21. A treatment method according to claim 20, wherein the ion beam has a scan rate V of between 0.01 mm/s and 1000 mm/s and a radius R of between 0.1 mm and 100 mm.

22. A treatment method according to claim 16, wherein the beam power is greater than or equal to 10 W and/or less than or equal to 2000 W.

23. A treatment method according to claim 16, wherein the dose of ions per unit of surface area is greater than or equal to 10¹⁸ ions/cm².

24. A treatment method according to claim 16, wherein the ion beam makes a pass or a plurality of passes over the same area of the surface of the metal element being treated, and the dose of ions per unit of surface area and per pass is greater than or equal to 0.5×10¹⁷ ions/cm² per pass.

25. A treatment method according to claim 24, wherein the ion beam makes a pass or a plurality of passes over the same area of the surface of the metal element being treated, and the dose of ions per unit of surface area and per pass is less than or equal to 100×10¹⁷ ions/cm² per pass.

26. A treatment method according to claim 16, wherein the thickness e_{I} of the implantation area is greater than or equal to 0.1 μm and/or less than or equal to 1 μm.

27. A treatment method according to claim 16, wherein the thickness e_{I}+e_{D} of the implantation-diffusion area is greater than or equal to 1 μm and/or less than or equal to 100 μm.

28. A treatment method according to claim 16, wherein the metal of the metal element is titanium (Ti) or a titanium alloy and:
T_{ZF}≦773 K and
T_{S}≧973 K.

29. A treatment method according to claim 16, wherein the metal of the metal element is iron (Fe) or an iron alloy, and:
T_{ZF}≦393 K and
T_{S}≧473 K.

30. A treatment method according to claim 16, wherein the metal of the metal element is aluminum (Al) or an aluminum alloy, and:
T_{ZF}≦543 K and
T_{S}≧597K.

31. A treatment method according to claim 21, wherein the ion beam has a scan rate V greater than or equal to 1 mm/s and/or less than or equal to 100 m/s.

32. A treatment method according to claim 21, wherein the ion beam has a radius R greater than or equal to 1 mm and/or less than or equal to 50 mm.

33. A treatment method according to claim 22, wherein the beam power is less than or equal to 1000 W.

34. A treatment method according to claim 23, wherein the dose of ions per unit of surface area is greater than or equal to 2×10¹⁸ ions/cm².

35. A treatment method according to claim 34, wherein the dose of ions per unit of surface area is greater than or equal to 4×10¹⁸ ions/cm².

36. A treatment method according to claim 24, wherein the dose of ions per unit of surface area and per pass is greater than or equal to 1×10¹⁷ ions/cm² per pass.

37. A treatment method according to claim 36, wherein the dose of ions per unit of surface area and per pass is greater than or equal to 2×10¹⁷ ions/cm² per pass.

38. A treatment method according to claim 25, wherein the dose of ions per unit of surface area and per pass is less than or equal to 50×10¹⁷ ions/cm² per pass.

39. A treatment method according to claim 38, wherein the dose of ions per unit of surface area and per pass is less than or equal to 20×10¹⁷ ions/cm² per pass.

40. A treatment method according to claim 27, wherein the thickness e_{I}+e_{D} of the implantation-diffusion area is less than or equal to 10 μm.

41. A treatment method according to claim 29, wherein the metal of the metal element is stainless steel.
